(19) United States
(12) Patent Application Publication
(10) Pub. No.: US 2024/0088051 A1
(43) Pub. Date: Mar. 14, 2024

(54) METHOD FOR PRODUCING SEMICONDUCTOR DEVICE, WIRING BOARD, AND SEMICONDUCTOR DEVICE

(71) Applicant: Resonac Corporation, Toyko (JP)

(72) Inventors: Kazuyuki MITSUKURA, Minato-ku, Tokyo (JP); Shunsuke OTAKE, Minato-ku, Tokyo (JP); Hiroaki FUJITA, Minato-ku, Tokyo (JP); Shinji SHIMAOKA, Minato-ku, Tokyo (JP); Takashi MASUKO, Minato-ku, Tokyo (JP); Kazuhiko KURAFUCHI, Minato-ku, Tokyo (JP)

(21) Appl. No.: 18/261,114

(22) PCT Filed: Jan. 12, 2022
(86) PCT No.: PCT/JP2022/000695

§ 371 Date: Jul. 12, 2023

(30) Foreign Application Priority Data
Jan. 14, 2021 (WO) PCT/JP2021/001029

(51) Int. Cl. H01L 23/538; H01L 21/48; H01L 23/00; H01L 25/00; H01L 25/065

(52) U.S. Cl. CPC H01L 23/5386; H01L 21/4846; H01L 24/08; H01L 24/16; H01L 24/19; H01L 24/20; H01L 25/0655; H01L 25/50; H01L 21/561; H01L 2224/08225; H01L 2224/19; H01L 2224/211

(57) ABSTRACT

A method for manufacturing a semiconductor device is disclosed. The method for manufacturing a semiconductor device includes preparing a base material, preparing a plurality of semiconductor elements each having a connection terminal, preparing a wiring board provided with a first wiring, arranging the plurality of semiconductor elements on the base material, covering the plurality of semiconductor elements on the base material with an insulating material, arranging the wiring board on at least one of the plurality of semiconductor elements so that the first wiring is connected to at least some of the connection terminals of the plurality of semiconductor elements covered with the insulating material, and forming a second wiring around the first wiring. The first wiring has finer wiring than the second wiring.

### TECHNICAL FIELD

The present disclosure relates to a method for manufacturing a semiconductor device, a wiring board, and a semiconductor device.

### BACKGROUND ART

Patent Literature 1 discloses a semiconductor device in which chips with different performances are mounted together in one package for the purpose of increasing the density and performance of a semiconductor package. In this semiconductor device, chips are connected to each other by using a high-density interconnect technology. Non Patent Literature 1 and Non Patent Literature 2 disclose a package-on-package (PoP) technology that is widely used in smartphones and tablet terminals. In this PoP technology, a different package is stacked on a package and connected thereto by using, for example, flip-chip mounting.

As further high-density mounting technologies, a packaging technology using an organic substrate with high-density wiring (organic interposer), a fan-out type packaging technology (FO-WLP) with a through mold via (TMV), a packaging technology using a silicon or glass interposer, a packaging technology using a through silicon via (TSV), a packaging technology using a chip embedded in a substrate for chip-to-chip transmission, and the like have been proposed. For example, in the organic interposer or the FO-WLP, it has been proposed to use a fine wiring layer for high-density conduction when semiconductor chips are mounted in parallel (see Patent Literature 2, for example). In addition, in the packaging technology using an organic substrate with high-density wiring, it has been proposed to embed a wiring layer on the surface of a core substrate, which is a low-density wiring layer, with a thermosetting resin and form a high-density wiring layer thereon (see Patent Literature 3, for example). Further, in the FO-WLP, it has been proposed to form a redistribution layer on a plurality of semiconductor chips embedded with an encapsulating material and make connections therebetween.

### CITATION LIST

### Patent Literature

Patent Literature 1: Japanese Unexamined Patent Publication No. 2012-529770
Patent Literature 2: U.S. Patent Application Publication No. 2011/0221071
Patent Literature 3: Japanese Unexamined Patent Publication No. H11-126978
Patent Literature 4: International Publication WO 2012/099133

### Non Patent Literature

Non Patent Literature 1: Application of Through Mold Via (TMV) as PoP Base Package, Electronic Components and Technology Conference (ECTC), 2008
Non Patent Literature 2: Advanced Low Profile PoP Solution with Embedded Wafer Level PoP (eWLB-PoP) Technology, ECTC, 2012

### SUMMARY OF INVENTION

### Technical Problem

As described above, many high-density mounting technologies have been proposed in the past. For example, in the FO-WLP among the high-density mounting technologies, a plurality of semiconductor chips are embedded with an encapsulating material and then a redistribution layer is formed on the semiconductor chips so as to connect the redistribution layer and the semiconductor chips to each other. However, there is a demand for further efficiency improvement or cost reduction of high-density mounting technologies including the FO-WLP.

It is an object of the present disclosure to provide a method for manufacturing a semiconductor device, a wiring board, and a semiconductor device through which the efficiency of a conventional semiconductor device manufacturing method can be improved.

### Solution to Problem

As one aspect of the present disclosure, there is provided a method for manufacturing a semiconductor device according to one aspect. The method for manufacturing a semiconductor device includes preparing a base material, preparing a plurality of semiconductor elements each having a connection terminal, preparing a wiring board provided with a first wiring, arranging the plurality of semiconductor elements on the base material, covering the plurality of semiconductor elements on the base material with an insulating material, arranging the wiring board on at least one of the plurality of semiconductor elements so that the first wiring is connected to at least some of the connection terminals of the plurality of semiconductor elements covered with the insulating material, and forming a second wiring around the first wiring. In this manufacturing method, the first wiring has finer wiring than the second wiring.

In the method for manufacturing a semiconductor device described above, the wiring board manufactured in advance is used as a component that can be applied to a portion of the device wiring of the semiconductor device that requires fine wiring. In this case, only anon-defective substrate with fine wiring can be mounted in a portion of the semiconductor device that requires fine wiring. Therefore, when manufacturing a semiconductor device, a fine wiring portion where defects are likely to occur compared with other portions is more reliably formed. As a result, the method for manufacturing a semiconductor device can be made more efficient. In addition, since the fine wiring portion in the semiconductor device can be formed more reliably, it is possible to improve the manufacturing yield of the semiconductor device. As a result, it is possible to reduce the manufacturing cost.

In the method for manufacturing a semiconductor device described above, the plurality of semiconductor elements may be arranged on the base material so that the connection terminals of the plurality of semiconductor elements face a side opposite to the base material. In this case, it is possible to mount the wiring board without removing the base material. In the method for manufacturing a semiconductor device described above, the plurality of semiconductor elements may be arranged on the base material so that the connection terminals of the plurality of semiconductor elements face the base material. In this case, it is possible to mount the wiring board without grinding the insulating resin after removing the base material.

As another aspect of the present disclosure, there is provided a method for manufacturing a semiconductor device according to another aspect. The method for manufacturing a semiconductor device includes preparing a base material, preparing a plurality of semiconductor elements each having a connection terminal, preparing a wiring board having a surface area of 2500 mm² or less and provided with a first wiring, arranging the wiring board on the base material, forming a second wiring on the base material and around the wiring board, arranging the plurality of semiconductor elements on the base material so that at least some of the connection terminals of the plurality of semiconductor elements are connected to the first wiring, and covering the plurality of semiconductor elements on the base material with an insulating material. In the method for manufacturing a semiconductor device, the first wiring has finer wiring than the second wiring.

In the method for manufacturing a semiconductor device described above, the wiring board manufactured in advance is used as a component that can be applied to a portion of the device wiring of the semiconductor device that requires fine wiring. In this case, only a non-defective substrate with fine wiring can be mounted in a portion of the semiconductor device that requires fine wiring. Therefore, when manufacturing a semiconductor device, a fine wiring portion where defects are likely to occur compared with other portions is more reliably formed. As a result, the method for manufacturing a semiconductor device can be made more efficient. In addition, since the fine wiring portion in the semiconductor device can be formed more reliably, it is possible to improve the manufacturing yield of the semiconductor device. As a result, it is possible to reduce the manufacturing cost.

In any one of the methods for manufacturing a semiconductor device described above, the wiring board may include a base insulating layer and the first wiring provided on the base insulating layer, and the first wiring may include wiring having a line width of 5 μm or less. In this case, the fine wiring portion in the semiconductor device can be made finer more reliably.

In any one of the methods for manufacturing a semiconductor device described above, it is preferable that the base insulating layer contains a glass cloth. In this case, it is possible to improve the strength of the base insulating layer while reducing the thickness of the base insulating layer. Therefore, it is possible to reduce the size of the semiconductor device by making the device wiring layer thin. In addition, it is possible to improve the efficiency when manufacturing the semiconductor device by improving the handleability of the wiring board when manufacturing the semiconductor device. In addition, it is possible to reduce the possibility of damaging the wiring board when manufacturing the semiconductor device. Therefore, it is also possible to reduce the manufacturing cost. In addition, in the method for manufacturing a semiconductor device, a base material of the glass cloth may have a thickness of 30 μm or more and 500 μm or less.

In any one of the methods for manufacturing a semiconductor device described above, the base insulating layer may have a thickness of 50 μm or more and 300 μm or less. In this case, it is possible to achieve both improvement in handleability of the wiring board and reduction in thickness of the semiconductor device.

In any one of the methods for manufacturing a semiconductor device described above, it is preferable that a thickness variation of the base insulating layer is 1% or less of an average thickness of the base insulating layer. In this case, it becomes easier to make the fine wiring formed on the insulating layer thinner. Therefore, it is possible to manufacture a smaller semiconductor device.

In any one of the methods for manufacturing a semiconductor device described above, the wiring board may include a wiring insulating layer covering the first wiring on the base insulating layer, and it is preferable that an insulating material forming at least one of the base insulating layer and the wiring insulating layer has a thermal expansion coefficient of 80 ppm/° C. or less. In this case, it is possible to suppress the warpage of the wiring board and the semiconductor device. In addition, the base insulating layer may be thicker than the wiring insulating layer.

In any one of the methods for manufacturing a semiconductor device described above, a surface of the base insulating layer on which the first wiring is formed may have a surface roughness of200 nm or less. The “surface roughness” referred to herein is the arithmetic mean roughness (Ra) specified in JIS B 0601:2001.

In any one of the methods for manufacturing a semiconductor device described above, the base insulating layer may be a laminate including a first insulating layer and a second insulating layer, and a surface roughness of the first insulating layer in contact with the first wiring may be larger than a surface roughness of the second insulating layer. In this case, it is possible to improve the adhesion between the first insulating layer and the fine wiring. In addition, since the surface roughness of the second insulating layer is small, it is possible to reduce the thickness variation of the entire insulating layer. In this case, the first insulating layer may contain a glass cloth, and the second insulating layer may not contain a glass cloth. In this manner, it is possible to reduce the thickness of the insulating layer while maintaining the strength of the insulating layer in the wiring board. In addition, it is possible to improve the adhesion to the fine wiring layer. The “surface roughness” referred to herein is the arithmetic mean roughness (Ra) specified in JIS B 0601:2001.

In any one of the methods for manufacturing a semiconductor device described above, it is preferable that the first wiring is directly connected to at least some of the connection terminals of the plurality of semiconductor elements. In this case, it is possible to further reduce the thickness of the semiconductor device.

In any one of the methods for manufacturing a semiconductor device described above, it is preferable that the first wiring of the wiring board is connected to at least two of the plurality of semiconductor elements. In this case, it is possible to connect the semiconductor elements to each other with high density.

In any one of the methods for manufacturing a semiconductor device described above, the second wiring may include a first end and a second end on a side opposite to the first end. The second wiring may be connected to at least some of the connection terminals of the plurality of semiconductor elements at the first end, and may be exposed from an insulating material covering the second wiring and connected to an external terminal at the second end. In this case, it is possible to more reliably connect the semiconductor element to the external terminal.

In any one of the methods for manufacturing a semiconductor device described above, the insulating material covering the second wiring may not contain a glass cloth. In this case, it is possible to reduce the thickness of the semiconductor device by making the wiring board thinner.

Still another aspect of the present disclosure relates to a wiring board. The wiring board is a wiring board used in any one of the methods for manufacturing a semiconductor device described above, and includes a base insulating layer, and a first wiring provided on the base insulating layer and including wiring having a line width of 5 μm or less. The wiring board has a surface area of 2500 mm² or less.

According to the wiring board described above, the wiring board can be used as a component that can be applied to a portion of the device wiring that requires fine wiring when manufacturing the semiconductor device. In this case, only a non-defective substrate with fine wiring can be mounted in a portion that requires fine wiring. Therefore, when manufacturing a semiconductor device, a fine wiring portion where defects are likely to occur compared with other portions is more reliably formed. As a result, the method for manufacturing a semiconductor device can be made more efficient. In addition, since the fine wiring portion can be formed more reliably, it is possible to improve the manufacturing yield of the semiconductor device. As a result, it is possible to reduce the manufacturing cost.

Still another aspect of the present disclosure relates to a semiconductor device. The semiconductor device includes device wiring, a plurality of semiconductor elements arranged on the device wiring, and an insulation encapsulating portion that covers the plurality of semiconductor elements with an insulating material. A wiring board having fine wiring connected to the plurality of semiconductor elements so as to bridge over the plurality of semiconductor elements, is embedded in the device wiring of the semiconductor device. According to this semiconductor device, it is possible to obtain a semiconductor device in which a fine wiring portion is reliably formed.

Still another aspect of the present disclosure relates to a method for manufacturing a wiring board. The method for manufacturing a wiring board includes forming a metal layer on an insulating layer, forming a resist pattern having a space width of 5 μm or less on the metal layer, forming a plurality of fine wirings with a line width of 5 μm or less in the resist pattern on the metal layer, peeling off the resist pattern, removing the metal layer to form a wiring board having a plurality of fine wirings provided on the insulating layer, and dividing the wiring board into individual pieces to obtain a plurality of substrates with fine wiring.

According to the method for manufacturing a wiring board described above, substrates with fine wiring obtained by division into individual pieces can be manufactured in advance as components that can be applied to a portion of the device wiring that requires fine wiring when manufacturing the semiconductor device. In this case, only a non-defective substrate with fine wiring can be mounted in a portion of the semiconductor device that requires fine wiring. Therefore, when manufacturing a semiconductor device, a fine wiring portion where defects are likely to occur compared with other portions is more reliably formed. As a result, the method for manufacturing a semiconductor device can be made more efficient. In addition, since the fine wiring portion in the semiconductor device can be formed more reliably, it is possible to improve the manufacturing yield of the semiconductor device. As a result, it is possible to reduce the manufacturing cost.

### Advantageous Effects of Invention

According to the present disclosure, it is possible to improve the efficiency of a method for manufacturing a semiconductor device.

### BRIEF DESCRIPTION OF DRAWINGS

FIG. 1 is a cross-sectional view showing an example of a wiring board.

FIGS. 2A to 2C are diagrams showing a method for manufacturing a wiring board.

FIG. 3 is a cross-sectional view showing an example of a semiconductor device.

FIGS. 4A to 4D are diagrams showing each step of a method for manufacturing a semiconductor device.

FIGS. 5A to 5D are diagrams showing each step of the method for manufacturing a semiconductor device, and are diagrams showing steps subsequent to the steps in FIGS. 4A to 4D.

FIGS. 6A to 6D are diagrams showing each step of a method for manufacturing a semiconductor device according to a modification example.

FIGS. 7A to 7C are diagrams showing each step of the method for manufacturing a semiconductor device according to the modification example, and are diagrams showing steps subsequent to the steps in FIGS. 6A to 6D.

FIGS. 8A to 8D are diagrams showing each step of a method for manufacturing a semiconductor device according to another modification example.

FIGS. 9A to 9C are diagrams showing each step of the method for manufacturing a semiconductor device according to another modification example, and are diagrams showing steps subsequent to the steps in FIGS. 8A to 8D.

FIG. 10 is a cross-sectional view showing a modification example of the wiring board.

### DESCRIPTION OF EMBODIMENTS

Hereinafter, the present embodiment will be described in detail with reference to the diagrams. In the following description, the same or equivalent portions are denoted by the same reference numerals, and repeated descriptions thereof will be omitted. It is assumed that the positional relationship such as up, down, right, and left is based on the positional relationship shown in the diagrams unless otherwise specified. The dimensional ratio of each diagram is not limited to the ratio shown in the diagram.

When terms such as “left”, “right”, “front”, “rear”, “top”, “bottom”, “upper”, “lower”, “first”, and “second” are used in this specification and claims, these are intended to be illustrative and do not necessarily mean that these are in the relative position at all times. The term “layer” includes not only a structure having a shape formed on the entire surface but also a structure having a shape partially formed when observed as a plan view. The term “step” includes not only an independent step but also a step whose intended purpose is achieved even if the step cannot be clearly distinguished from other steps. In the numerical ranges described stepwise in this specification, the upper limit value or lower limit value of the numerical range at one stage may be replaced with the upper limit value or lower limit value of the numerical range at another stage.

[Configuration of a Wiring Board]

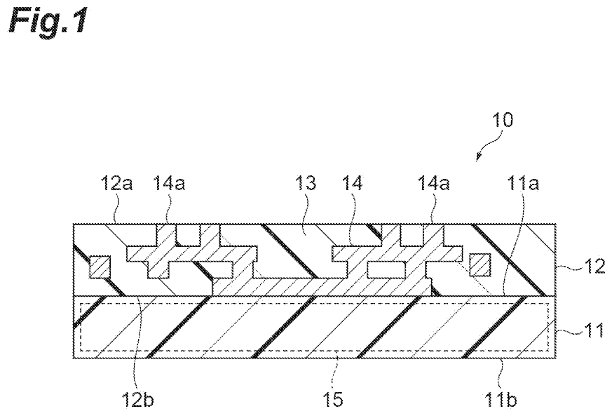

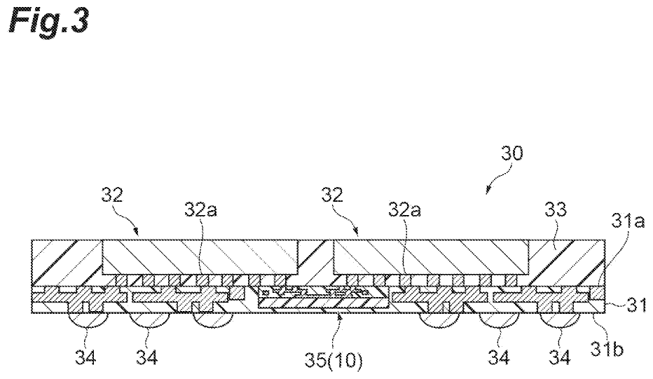

FIG. 1 is a cross-sectional view showing an example of a wiring board. As shown in FIG. 1, a wiring board 10 is, for example, a member used to form a redistribution layer (RDL) 35 of a device wiring layer 31 of a semiconductor device 30, which will be described later (see FIG. 3). The wiring board 10 may be used for wiring or connection in other configurations of the semiconductor device. The wiring board 10 includes an insulating layer 11 (base insulating layer) and a fine wiring layer 12. The wiring board 10 is a very small substrate that can be embedded in the device wiring layer 31, and may have, for example, a rectangular shape of 50 mm long by 50 mm wide or a rectangular shape of 20 mm long by 20 mm wide in plan view. As an example, the wiring board 10 has a surface area of 2500 mm² or less. The wiring board 10 may have a thickness of, for example, 0.1 mm or more and 1.0 mm or less.

The insulating layer 11 is, for example, a layer obtained by impregnating or coating a glass cloth 15 with a thermosetting resin composition and curing or semi-curing (B-staging) the resin by heating or the like. The insulating layer 11 may not contain the glass cloth 15. The thermosetting resin contained in the insulating layer 11 is not particularly limited. Examples thereof include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. The thermosetting resin contained in the insulating layer 11 is such a single resin or a mixture of two or more of these resins. The insulating layer 11 may contain an epoxy resin or a cyanate resin as a thermosetting resin from the viewpoint of moldability or electrical insulation.

A modified silicone compound, a curing agent, a curing accelerator, an inorganic filler, a thermoplastic resin, an elastomer, an organic filler, a flame retardant, an ultraviolet absorber, an antioxidant, a photopolymerization initiator, a fluorescent brightener, an adhesion improver, and the like described in International Publication WO 2012/099133 can be added to the thermosetting resin contained in the insulating layer 11 as necessary.

The glass cloth 15 contained in the insulating layer 11 is used, for example, in laminates for various electrical insulating materials. Examples of the material of the glass cloth 15 include E glass, D glass, S glass, Q glass, and mixtures thereof. These glass cloths 15 may have shapes of woven fabric, non-woven fabric, roving, chopped strand mat, surfacing mat, and the like, for example. The material and shape are selected according to the intended use or performance of the molded article, and if necessary, one or two or more types of materials and shapes can be combined. The thickness of the base material of the glass cloth is not particularly limited, but can be, for example, 30 μm or more and 500 μm or less. By using a base material surface-treated with a silane coupling agent or the like or a base material subjected to mechanical fiber opening treatment for the glass cloth 15, the insulating layer 11 can have heat resistance, moisture resistance, or workability.

The insulating layer 11 has a first surface 11a facing the fine wiring layer 12 and a second surface 11b on the opposite side, and has a thickness of, for example, 50 μm or more and 500 μm or less. The thickness of the insulating layer 11 may be 100 μm or more and 300 μm or less from the viewpoint of compatibility between handleability and thinness, and may be 50 μm or more and 300 μm or less or may be 50 μm or more and 200 μm or less from the viewpoint of reducing thickness variations. The insulating layer 11 may have a thermal expansion coefficient (after curing) of, for example, 80 ppm/° C. or less from the viewpoint of suppressing warpage. The insulating layer 11 may have a thermal expansion coefficient (after curing) of, for example, 70 ppm/° C. or less from the viewpoint of suppressing peeling or cracking in the reflow process and temperature cycle test. The insulating layer 11 may have a linear expansion coefficient (after curing) of 20 ppm/° C. or more.

The thickness variation of the insulating layer 11 may be 1% or less of the average thickness of the insulating layer 11. By suppressing the thickness variation within 1% of the average thickness, the flatness of the insulating layer 11 is stabilized. As a result, the yield in forming the fine wiring layer 12 on the insulating layer 11 can be improved. From the viewpoint of further improving the yield, the thickness variation may be suppressed within 0.8% of the average thickness of the insulating layer 11. The thickness variation can be measured by observing the thickness of the insulating layer 11 using an electron microscope. Any ten points are measured, and the average thickness is calculated. Then, the percentage of the deviation of each thickness at the measured location (10 locations) deviates from the average thickness is calculated. As the value of the thickness variation of the insulating layer 11, in terms of reducing focus deviation during exposure, the deviation of each thickness at the measured location may be within 3 μm from the average thickness, or may be 2.5 μm or less from the average thickness.

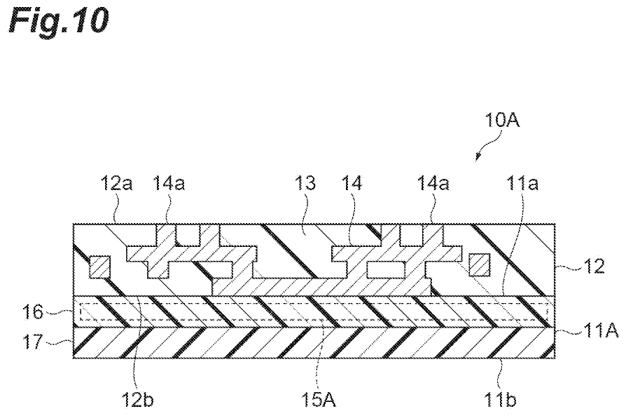

The first surface 11a of the insulating layer 11 may have a surface roughness Ra of, for example, 200 nm or less, or may have a surface roughness Ra larger than 200 nm. The surface roughness Ra is the arithmetic mean roughness (Ra) specified in JIS B 0601 2001. The insulating layer 11 may be a laminate including two or more insulating layers including a first insulating layer 16 and a second insulating layer 17 (see FIG. 10). In this case, the surface roughness Ra of the first insulating layer 16 may be larger than the surface roughness Ra of the second insulating layer 17. For example, the insulating layer 11 can be formed by combining the first insulating layer 16 having a surface roughness Ra larger than 200 nm and the second insulating layer 17 having a surface roughness Ra of 200 nm or less. By using the first insulating layer 16 having a surface roughness Ra exceeding 200 nm, it is possible to secure high adhesion with a copper foil forming a part of the fine wiring layer 12. Here, the surface roughness Ra of the first insulating layer 16 referred to herein is the surface roughness of a surface facing the fine wiring layer 12, and the surface roughness Ra of the second insulating layer 17 referred to herein is the surface roughness Ra of a surface on a side (lower side in the diagram) opposite to the fine wiring layer 12.

When the insulating layer 11 includes the first insulating layer 16 and the second insulating layer 17, the first insulating layer 16 can contain a glass cloth 15A and the second insulating layer 17 cannot contain the glass cloth. By containing the glass cloths 15 and 15A in the insulating layer 11, the strength of the insulating layer 11 can be improved, and the linear expansion coefficient can be reduced. On the other hand, since the insulating layer 11 has a layer portion (the second insulating layer 17) that does not contain the glass cloth, the thickness variation and surface roughness of the insulating layer 11 can be reduced. By forming the insulating layer 11 using the first insulating layer 16 and the second insulating layer 17 having different structures, it is possible to achieve both the high strength and low linear expansion coefficient of the insulating layer 11 and the low thickness variation and low surface roughness of the insulating layer 11.

The second insulating layer 17 forming the insulating layer 11 is not particularly limited, but may be a photosensitive insulating layer. A photosensitive redistribution material and a solder resist can be used as the photosensitive insulating layer. The second insulating layer 17 may be formed by using either a film-shaped material or a liquid-form material.

As shown in FIGS. 1 and 10, a copper foil may be formed on the first surface 11a of the insulating layer 11. The copper foil may be a low-roughness type copper foil whose surface roughness Ra is controlled to be equal to or less than 300 nm. Such a copper foil can form a part (base end portion) of the fine wiring layer 12. An adhesive layer may be formed on the second surface 11b of the insulating layer 11. The adhesive layer is not particularly limited, but may be formed by using a film-shaped adhesive from the viewpoint of handleability. For example, the adhesive layer may be formed by using a die attach film or a film underfill. The film-shaped adhesive can be formed by lamination. The lamination temperature may be 60° C. or higher and 120° C. or lower from the viewpoint of reducing the tackiness of the adhesive layer and suppressing the warpage of the substrate.

The fine wiring layer 12 is formed by providing a copper wiring 14 (first wiring) having a three-dimensional wiring structure in an insulating layer 13 (wiring insulating layer). The copper wiring 14 is wiring having a fine line width of, for example, 0.5 μm or more and 5 μm or less. The copper wiring 14 preferably has a fine line width of 0.7 μm or more and 4 μm or less, more preferably 1 μm or more and 3 μm or less. A connection ends 14a of the copper wiring 14 are exposed from a first surface 12a of the fine wiring layer 12 to the outside. The connection ends 14a of the copper wiring 14 are electrically and mechanically connected to connection terminals of different semiconductor elements or one semiconductor element. A second surface 12b of the fine wiring layer 12 is adhered and fixed to the first surface 11a of the insulating layer 11. By sequentially stacking respective wiring layers from the second surface 12b toward the first surface 12a as will be described later, the copper wiring 14 forms a three-dimensional wiring layer.

The insulating layer 13 is formed by stacking a plurality of layers. For example, from the viewpoint of forming fine vias and grooves, each layer may have a thickness of 10 μm or less or may have a thickness of 5 μm or less. On the other hand, each insulating layer 13 may have a thickness of 1 μm or more from the viewpoint of electrical reliability. The insulating layer 13 may have a thickness of 10 μm or more and 100 μm or less as a whole. The insulating layer 13 may have a thermal expansion coefficient (after curing) of, for example, 80 ppm/° C. or less from the viewpoint of suppressing warpage. The insulating layer 13 may have a thermal expansion coefficient (after curing) of, for example, 70 ppm/° C. or less from the viewpoint of suppressing peeling or cracking in the reflow process and temperature cycle test. On the other hand, the insulating layer 13 may have a linear expansion coefficient (after curing) of 20 ppm/° C. or more from the viewpoint of forming fine vias or grooves by improving stress relaxation. The linear expansion coefficient of the insulating layer 13 may be the same as the linear expansion coefficient of the insulating layer 11, or may be smaller or larger than the linear expansion coefficient of the insulating layer 11. By making the linear expansion coefficient of the insulating layer 13 smaller than the linear expansion coefficient of the insulating layer 11, it is possible to more reliably suppress the warpage of the insulating layer 13 on a side connected to the semiconductor element or the like.

Such an insulating layer 13 is formed of materials such as a polyimide resin, a maleimide resin, an epoxy resin, a phenoxy resin, a polybenzoxazole resin, an acrylic resin, an acrylate resin, or a silica filler. The insulating layer 13 may contain a filler, and from the viewpoint of forming a fine portion, the contained filler may have an average particle diameter of 500 nm or less. The filler may be contained in the insulating layer 13 so that the content of the filler with respect to the total amount of the insulating material is less than 1% by mass. The insulating layer 13 may not contain a filler. The insulating layer 13 may not contain the glass cloth 15 contained in the insulating layer 11.

[Method for Manufacturing a Wiring Board]

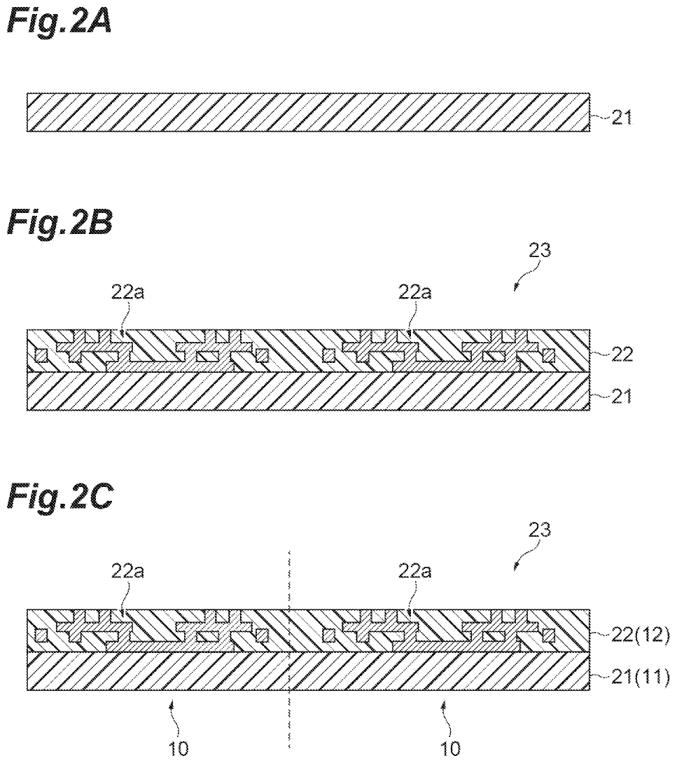

Next, a method for manufacturing the wiring board 10 will be described with reference to FIGS. 2A to 2C. As shown in FIG. 2A, first, an insulating layer 21 corresponding to the insulating layer 11 is prepared. As described above, the insulating layer 21 is a layer obtained by impregnating or coating a glass cloth with a thermosetting resin composition and curing or semi-curing (B-staging) the resin by heating or the like. The insulating layer 21 is, for example, wafer-shaped or panel-shaped, and is not particularly limited. For example, the insulating layer 21 may be a circular wafer with a diameter of 200 mm, 300 mm, or 450 mm, or may be a rectangular panel with a side of 300 mm or more and 700 mm or less. From the viewpoint of productivity, the insulating layer 21 may be, for example, a rectangular panel of 400 mm square or more.

Subsequently, a fine wiring layer 22 corresponding to the fine wiring layer 12 is formed. A method for forming the fine wiring layer 22 is not particularly limited, but a semi-additive process (SAP) or a trench method can be used. When forming a seed layer, an electroless plating method or a sputtering method can be used even though there is no particular limitation as long as a metal layer can be formed on the surface layer of the insulating layer 21, which is a wiring board, through the method.

In one example of the method for forming the fine wiring layer 22, first, a metal layer (seed layer) is formed on the insulating layer 21. The method for forming the metal layer by electroless plating is not particularly limited, but the resin surface of the insulating layer 21 is roughened by desmear or plasma, and the metal layer is formed on the roughened surface. As a method for forming fine wiring with a good yield, it is preferable to form the metal layer by increasing the surface energy of the resin surface while suppressing the roughening of the resin surface by emitting ultraviolet rays of 200 nm or less. As a method for emitting ultraviolet rays of 200 nm or less, for example, a low-pressure mercury lamp can be used. As a method for suppressing surface roughening, the metal layer can also be formed by sputtering. By suppressing the roughening of the resin surface, the seed layer can be easily removed. The thickness of the metal layer to be formed may be 200 nm or less from the viewpoint of improving the yield when forming the fine wiring.

Subsequently, a resist pattern is formed on the metal layer formed on the insulating layer 21. The resist pattern has a space width of, for example, 0.5 μm or more and 5 μm or less in a groove portion. The resist used for the resist pattern may be either a liquid-form resist or a film-shaped resist. The resist pattern can be formed by exposure using a stepper exposure machine and development using an alkaline aqueous solution.

As a method for forming vias or grooves in the resist pattern, laser ablation, photolithography, imprinting, and the like can be used. From the viewpoint of miniaturization and cost, a photolithography process can be used. In this case, a photosensitive resin material can be used as an insulating material. As a method for exposing the photosensitive resin material, a projection exposure method, a contact exposure method, a direct exposure method, and the like that are known can be used. As a developing method, an alkaline aqueous solution such as sodium carbonate or TMAH can be used. After forming vias and grooves, the insulating layer may be further cured by heating. This may be performed under the conditions in which the heating temperature may be 100° C. or higher and 200° C. or lower, and the heating time may be 30 minutes or longer and 3 hours or shorter.

Subsequently, by electroplating, a copper wiring portion is formed on the metal layer and in the grooves of the resist pattern. The thickness of the metal layer may be 10 μm or less from the viewpoint of improving the yield when forming the fine wiring. When the space width of the resist pattern is 0.5 μm or more and 5 μm or less, the line width of the copper wiring portion in the resist pattern formed by electrolytic plating is also 0.5 μm or more and 5 μm or less. After the copper wiring portion is formed, the resist pattern is peeled off and the metal layer is removed. The peeling of the resist pattern is performed by using a known method. The removal of the metal layer is performed by using a commercially available etchant.

By repeating the formation of such a wiring layer, a wiring board 23 in which the fine wiring layer 22 is provided on the insulating layer 21 is formed as shown in FIG. 2B. In the fine wiring layer 22, a plurality of fine wiring layers 22a each of which corresponds to the fine wiring layer 12 of the wiring board 10 are provided.

Subsequently, as shown in FIG. 2C, the wiring board 23 is divided into individual pieces to obtain a plurality of wiring boards 10. Although only two wiring boards 10 are shown in FIG. 2C for convenience of explanation, a large number of wiring boards 10 can be collectively manufactured. As a method for dividing the wiring board 23 into individual pieces, for example, a dicing machine is used to perform cutting.

[Configuration of a Semiconductor Device]

Next, the configuration of the semiconductor device 30 in which the wiring board 10 described above is embedded as a fine wiring layer will be described with reference to FIG. 3. As shown in FIG. 3, the semiconductor device 30 includes the device wiring layer 31, a plurality of semiconductor elements 32 (“a pair of semiconductor elements 32” in the example of FIG. 3) arranged on the device wiring layer 31, an insulation encapsulating portion 33 covering the plurality of semiconductor elements 32, and external terminals 34 for electrically connecting the semiconductor elements 32 to an external device. The external terminals 34 are formed of metal. For example, the external terminals 34 are formed of copper or solder.

The device wiring layer 31 of the semiconductor device 30 is a wiring layer having one end connected to connection terminals 32a of the plurality of semiconductor elements 32 and the other end connected to the external terminals 34. The device wiring layer 31 may be configured such that the terminal pitch on the semiconductor element 32 side is increased on the external terminal 34 side. In the device wiring layer 31, the wiring board 10 functioning as the redistribution layer 35 is embedded. In the example shown in FIG. 3, the wiring board 10 is connected to the plurality of semiconductor elements 32 so as to bridge over the plurality of semiconductor elements 32. The wiring board 10 may be connected so as to correspond to each semiconductor element 32. The wiring (copper wiring 14) of the wiring board 10 is finer wiring than other wiring of the device wiring layer 31 provided around the copper wiring 14. Since the wiring board 10 manufactured in advance so as to have such fine wiring is used in the semiconductor device 30, the semiconductor device 30 becomes a semiconductor device in which a fine wiring portion is reliably formed.

[Method for Manufacturing a Semiconductor Device]

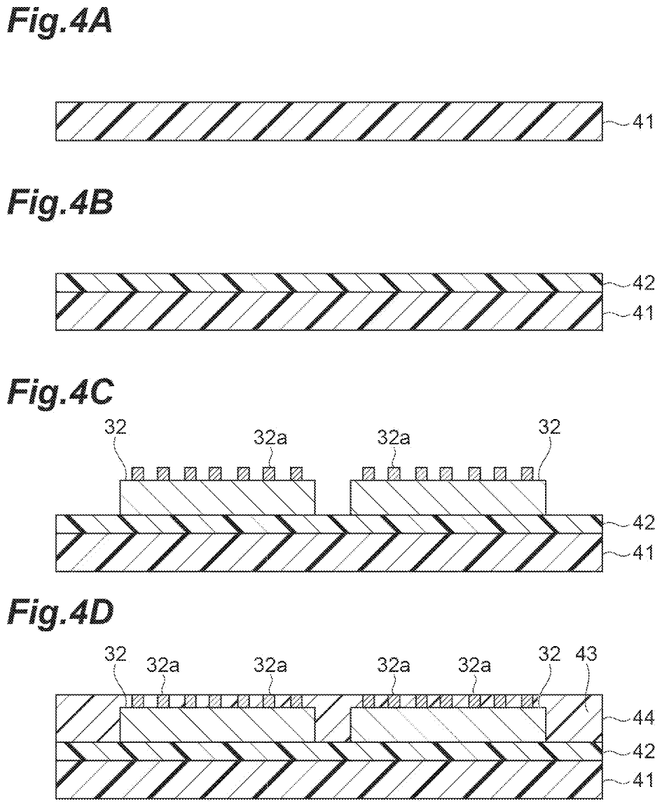

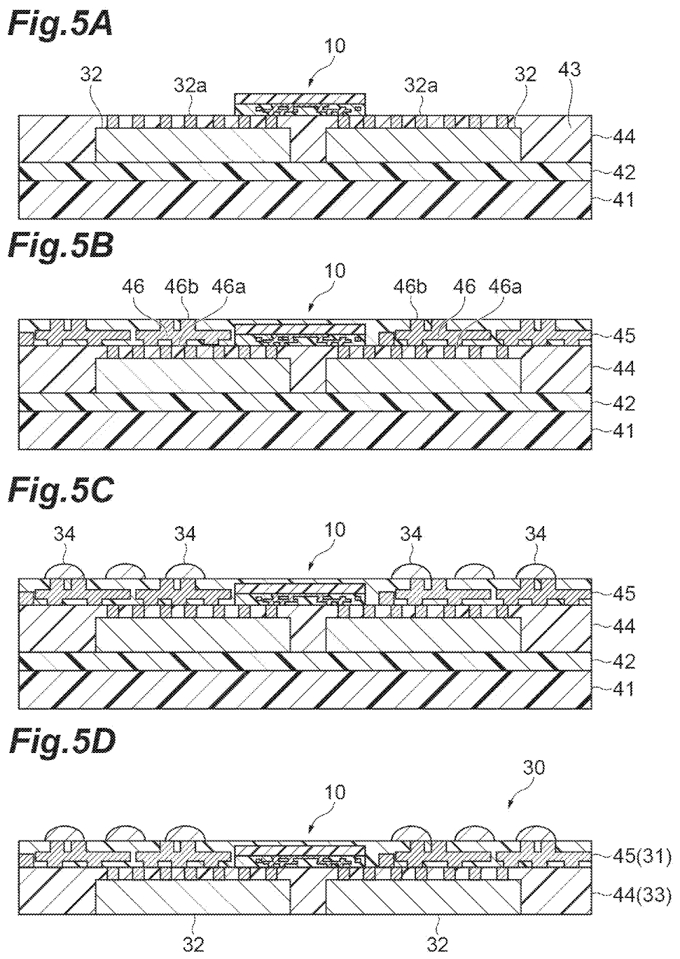

Next, a method for manufacturing (packaging) the semiconductor device described above will be described with reference to FIGS. 4A to 4D and 5A to 5D. Such a manufacturing method can be applied to, for example, a form that requires miniaturization and a large number of pins, and may be applied to a package form that requires an interposer for mixed mounting of different types of chips.

First, as shown in FIG. 4A, a base material 41 is prepared. As the base material 41, for example, a silicon substrate, a glass substrate, a metal plate such as SUS, a resin plate such as a copper clad laminate, an organic substrate, or a ceramic substrate can be used. The base material 41 is not particularly limited, but may be, for example, a rectangular panel with a side of 300 mm or more and 700 mm or less, or may be a rectangular panel of 400 mm square or more from the viewpoint of productivity. The base material 41 is not particularly limited, but may be a base material having a thickness of 0.4 mm or more and 1.5 mm or less. The base material 41 may be a base material having a thickness of 0.8 mm or more and 1.5 mm or less from the viewpoint of suppressing warpage, or may be a base material having a thickness of 0.4 mm or more and 1.2 mm or less from the viewpoint of making the package thin.

Subsequently, as shown in FIG. 4B, a resin layer 42 is formed on the top surface of the base material 41. The resin layer 42 is not particularly limited as long as it is possible to fix semiconductor elements, but may be an adhesive layer, such as a die bonding film, or a temporary fixing layer that can be peeled off by heating or laser.

A plurality of semiconductor elements 32 having connection terminals 32a are prepared. The semiconductor element 32 is not particularly limited, but may be, for example, a graphic processing unit GPU, a volatile memory such as a DRAM or an SRAM, a nonvolatile memory such as a flash memory, an RF chip, a chip with performance according to a combination thereof, a silicon photonics chip, a MEMS, or a sensor chip. The semiconductor element 32 may be a semiconductor element having a TSV.

The wiring board 10 shown in FIG. 1 is prepared. The wiring board 10 can be manufactured by using, for example, the method shown in FIGS. 2A to 2C, but may be manufactured by using other methods as long as the wiring board 10 is manufactured in advance. The wiring board 10 is a very small substrate and has a surface area of, for example, 2500 mm² or less.

After the preparation for the base material 41, the plurality of semiconductor elements 32, and the wiring board 10 is completed, the semiconductor elements 32 are mounted on the resin layer 42 as shown in FIG. 4C. As this mounting method, a die bonder or a flip chip bonder can be used. The mounting temperature is not particularly limited, but is, for example, 80° C. or higher and 200° C. or lower. The semiconductor element 32 is attached to the resin layer 42 by pressure bonding while being heated to such a temperature range. At the time of this attachment, the semiconductor element 32 is attached so that the connection terminals 32a face a side opposite to the base material 41.

Subsequently, as shown in FIG. 4D, the semiconductor elements 32 are covered with an insulating material 43 on the base material 41 so that the connection terminals 32a of the semiconductor elements 32 are exposed. As a result, an insulation encapsulating portion 44 is formed. The insulation encapsulating portion 44 may be formed on the semiconductor elements 32, and the connection terminals 32a may be exposed to the outside by opening or grinding. As the insulating material 43 for forming the insulation encapsulating portion 44, for example, a build-up material, a encapsulating material, or a photosensitive insulating material such as a solder resist or a redistribution material can be used.

As a method for opening the insulation encapsulating portion 44, laser ablation, photolithography, imprinting, and the like can be used. From the viewpoint of miniaturization and cost, a photolithography process may be used. In this case, the insulating material may be a photosensitive resin material. For example, the insulating material may be a photosensitive solder resist.

Subsequently, as shown in FIG. 5A, the wiring board 10 is arranged on the plurality of semiconductor elements 32 so as to connect the plurality of semiconductor elements 32 (two semiconductor elements 32 in one example) to each other. At this time, the wiring board 10 is directly connected to some of the connection terminals 32a of the plurality of semiconductor elements 32, and is arranged on the plurality of semiconductor elements 32 so as to bridge over the plurality of semiconductor elements 32. In this manner, the semiconductor elements 32 can be connected to each other with high density. Another wiring layer may be provided between the semiconductor element 32 and the wiring board 10, so that the semiconductor element 32 and the wiring board 10 may be connected to each other through another wiring layer. The wiring board 10 may be connected to the semiconductor element 32 by soldering, and the gap may be filled with an underfill material. The wiring board 10 may be a wiring board on which an underfill material is formed. As the underfill material, a capillary underfill, a mold underfill, a paste underfill, or a film underfill can be used.

Subsequently, as shown in FIG. 5B, the wiring board 10 is covered with an insulating material, and a device wiring layer 45 for transmitting an electrical signal from the semiconductor element 32 to the external terminal is formed. As an insulating material used for the device wiring layer 45, for example, a build-up material, an encapsulating material, or a photosensitive insulating material such as a solder resist or a redistribution material can be used. A wiring 46 (second wiring) in the device wiring layer 45 is wiring provided in the insulating material, and has a line width larger than that of the copper wiring 14 of the wiring board 10. In other words, the copper wiring 14 of the wiring board 10 is finer wiring than the wiring 46. The wiring 46 includes one end 46a (first end) on the semiconductor element 32 side and the other end 46b (second end) on the opposite side. The wiring 46 is connected to the connection terminals 32a of the plurality of semiconductor elements 32 at one end 46a, and is exposed from the insulating material covering the wiring 46 and connected to the external terminals 34 at the other end 46b.

Subsequently, as shown in FIG. 5C, the external terminals 34 are formed. The external terminals 34 may be formed of metal such as copper or solder, and are provided so as to be electrically and mechanically connected to the other end 46b of the wiring 46 of the device wiring layer 45. Although the wiring board 10 is not connected to the external terminal 34 in FIGS. 5A to 5D, the wiring board 10 may be connected to the external terminal 34. Although the wiring board 10 forms a part of the device wiring layer 45 but is not connected to the other wiring layer portion of the device wiring layer 45, the wiring board 10 may be connected to the other wiring layer portion.

Subsequently, as shown in FIG. 5D, when the formation of the external terminals 34 is completed, the resin layer 42 and the base material 41 are removed from the insulation encapsulating portion 44 to obtain the semiconductor device 30. As described above, the semiconductor device 30 is configured such that the wiring board 10 is embedded in the fine wiring layer portion of the device wiring layer 45 of the semiconductor device 30.

As described above, in the method for manufacturing a semiconductor device according to the present embodiment, the wiring board 10 manufactured in advance is used as a component that can be applied to a portion of the device wiring layer 31 of the semiconductor device 30 that requires fine wiring. Thus, only the non-defective wiring board 10 can be mounted in a portion of the semiconductor device 30 that requires fine wiring. Therefore, when manufacturing the semiconductor device 30, the fine wiring portion where defects are likely to occur compared with other portions is more reliably formed. As a result, the method for manufacturing the semiconductor device 30 can be made more efficient. In addition, since the fine wiring portion in the semiconductor device 30 can be formed more reliably, it is possible to improve the manufacturing yield of the semiconductor device 30. As a result, it is possible to reduce the manufacturing cost.

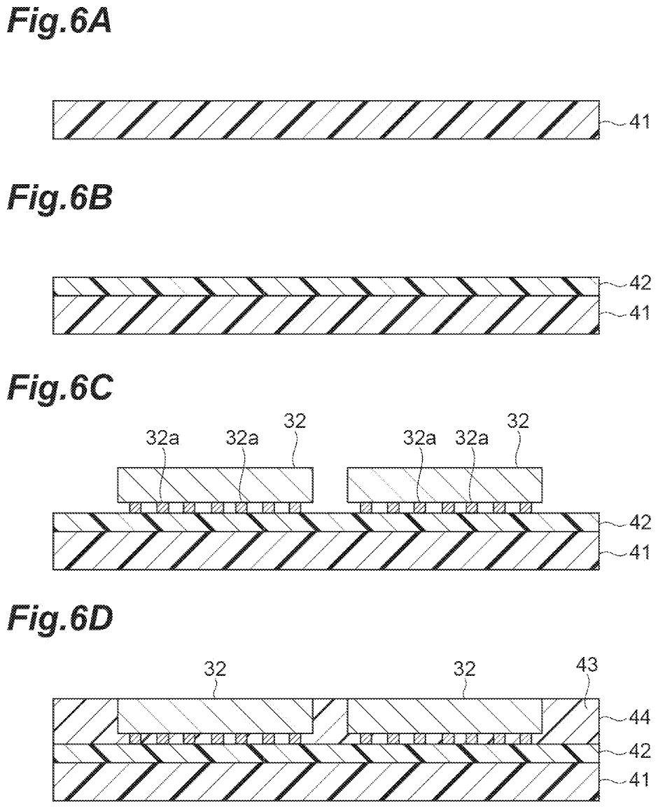

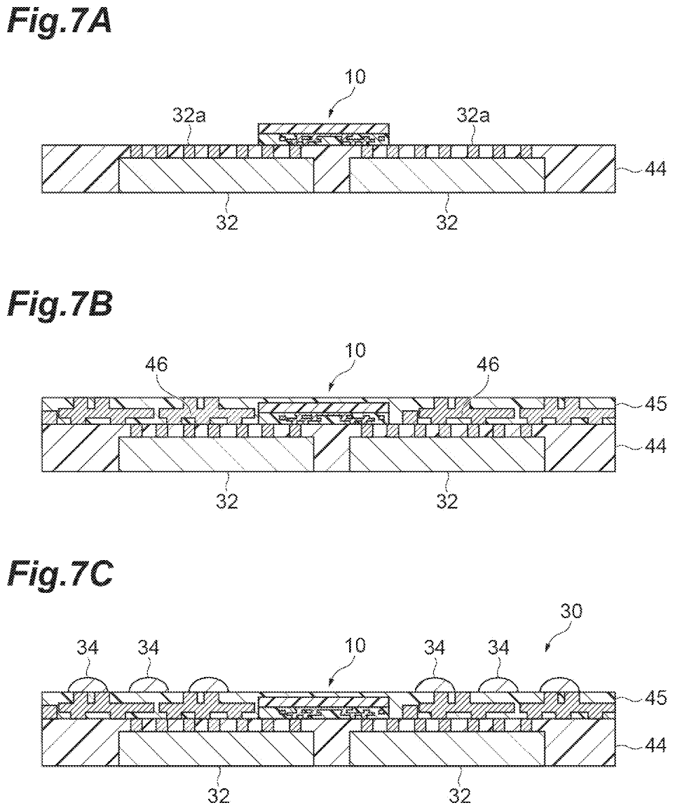

The method for manufacturing the semiconductor device 30 is not limited to the manufacturing method described above, and other methods may be used. For example, as a modification example of the semiconductor device manufacturing method, a manufacturing method shown in FIGS. 6A to 6D and 7A to 7C may be used. In this manufacturing method, the base material 41, the resin layer 42, and the like are prepared as shown in FIGS. 6A and 6B, and then the semiconductor elements 32 are mounted on the base material 41 as shown in FIG. 6C. In this modification example, the semiconductor elements 32 are arranged on the base material 41 so that the connection terminals 32a face the base material 41. Then, as shown in FIG. 6D, the semiconductor elements 32 are encapsulated with the insulating material 43 to form the insulation encapsulating portion 44. Thereafter, the base material 41 and the like are removed from the insulation encapsulating portion 44.

Subsequently, as shown in FIG. 7A, the wiring board 10 is connected to the connection terminals 32a of the semiconductor elements 32 encapsulated with the insulation encapsulating portion 44. Then, as shown in FIG. 7B, the wiring board 10 is covered with an insulating material, and the device wiring layer 45 for transmitting electrical signals from the semiconductor elements 32 to the external terminals is formed by using the wiring board 10. Thereafter, as shown in FIG. 7C, the external terminals 34 are formed to obtain the semiconductor device 30. In this case as well, similarly to the method described above, only the non-defective wiring board 10 can be mounted in a portion of the semiconductor device 30 that requires fine wiring. Therefore, when manufacturing the semiconductor device 30, the fine wiring portion where defects are likely to occur compared with other portions is more reliably formed. As a result, the method for manufacturing the semiconductor device 30 can be made more efficient. In addition, since the fine wiring portion in the semiconductor device 30 can be formed more reliably, it is possible to improve the manufacturing yield of the semiconductor device 30. As a result, it is possible to reduce the manufacturing cost.

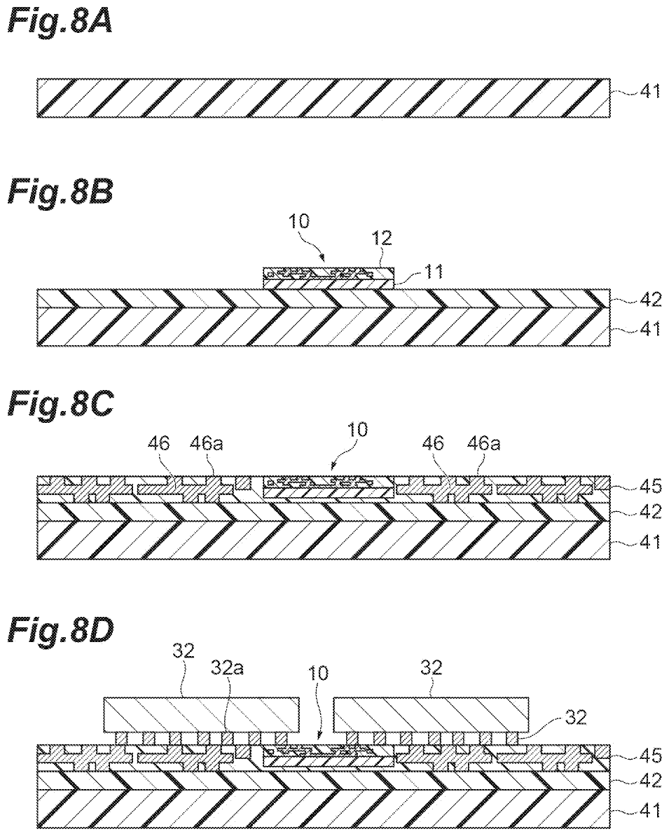

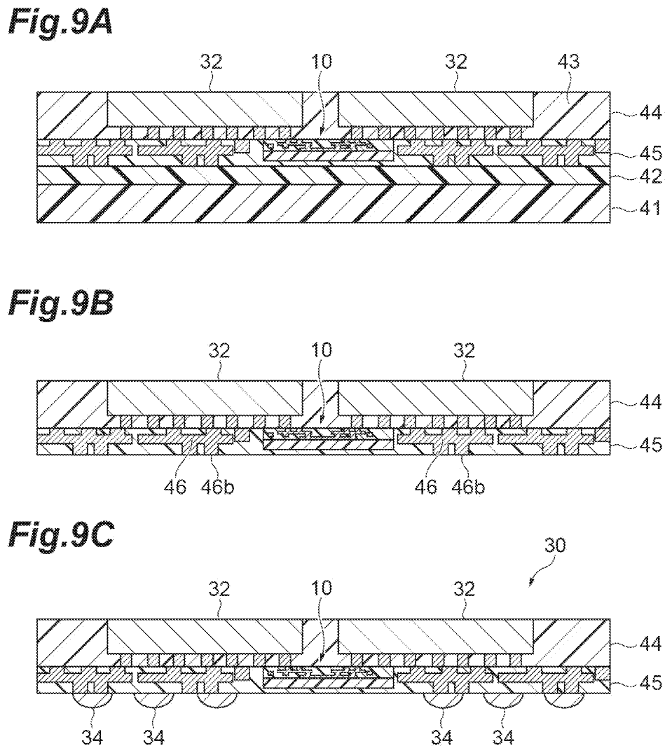

The method for manufacturing the semiconductor device 30 may be a manufacturing method according to still another modification example shown in FIGS. 8A to 8D and 9A to 9C. In this manufacturing method, as shown in FIGS. 8A and 8B, the base material 41 and the resin layer 42 are prepared and then the wiring board 10 is first mounted on the base material 41. At this time, the insulating layer 11 of the wiring board 10 is arranged so as to be in contact with the resin layer 42. Then, as shown in FIG. 8C, the wiring board 10 is covered with an insulating layer, and the device wiring layer 45 for transmitting electrical signals from the semiconductor elements 32 to the external terminals is formed by using the wiring board 10. Thereafter, a plurality of semiconductor elements 32 are mounted on the device wiring layer 45 so as to bridge over the wiring board 10. At this time, the connection terminals 32a of the semiconductor elements 32 are connected to each connection terminal of the fine wiring layer 12 of the wiring board 10 and the terminals of other wiring portions of the device wiring layer 45.

Subsequently, as shown in FIG. 9A, the semiconductor elements 32 are encapsulated with the insulating material 43 to form the insulation encapsulating portion 44. Then, as shown in FIG. 9B, the base material 41 and the like are removed from the insulation encapsulating portion 44 in the same manner as described above. Thereafter, as shown in FIG. 9C, the external terminals 34 are formed to obtain the semiconductor device 30. In this case as well, similarly to the method described above, only the non-defective wiring board 10 can be mounted in a portion of the semiconductor device 30 that requires fine wiring. Therefore, when manufacturing the semiconductor device 30, the fine wiring portion where defects are likely to occur compared with other portions is more reliably formed. As a result, the method for manufacturing the semiconductor device 30 can be made more efficient. In addition, since the fine wiring portion in the semiconductor device 30 can be formed more reliably, it is possible to improve the manufacturing yield of the semiconductor device 30. As a result, it is possible to reduce the manufacturing cost.

While the wiring board, the method for manufacturing a wiring board, the semiconductor device, and the method for manufacturing a semiconductor device according to embodiments of the present disclosure have been described above, the present disclosure is not limited to the above-described embodiments, and modifications can be made as appropriate without departing from the scope of the present disclosure.

### REFERENCE SIGNS LIST

10: wiring board, 11: insulating layer (base insulating layer), 12: fine wiring layer, 13: insulating layer (wiring insulating layer), 14: copper wiring (first wiring), 21: insulating layer, 22: fine wiring layer, 23: wiring board, 30: semiconductor device, 31: device wiring layer, 32: semiconductor element, 32a: connection terminal, 33: insulation encapsulating portion, 34: external terminal, 35: redistribution layer (RDL), 41: base material, 42: resin layer, 43: insulating material, 44: insulation encapsulating portion, 45: device wiring layer, 46: wiring (second wiring).

1. A method for manufacturing a semiconductor device, comprising:
preparing a base material;
preparing a plurality of semiconductor elements each having a connection terminal;
preparing a wiring board provided with a first wiring;
arranging the plurality of semiconductor elements on the base material;
covering the plurality of semiconductor elements on the base material with an insulating material;
arranging the wiring board on at least one of the plurality of semiconductor elements so that the first wiring is connected to at least some of the connection terminals of the plurality of semiconductor elements covered with the insulating material; and
forming a second wiring around the first wiring,
wherein the first wiring has finer wiring than the second wiring.

2. The method for manufacturing a semiconductor device according to claim 1,
wherein the plurality of semiconductor elements are arranged on the base material so that the connection terminals of the plurality of semiconductor elements face a side opposite to the base material.

3. The method for manufacturing a semiconductor device according to claim 1,
wherein the plurality of semiconductor elements are arranged on the base material so that the connection terminals of the plurality of semiconductor elements face the base material.

4. A method for manufacturing a semiconductor device, comprising:
preparing a base material;
preparing a plurality of semiconductor elements each having a connection terminal;
preparing a wiring board having a surface area of 2500 mm² or less and provided with a first wiring;
arranging the wiring board on the base material;
forming a second wiring on the base material and around the wiring board;
arranging the plurality of semiconductor elements on the base material so that at least some of the connection terminals of the plurality of semiconductor elements are connected to the first wiring; and
covering the plurality of semiconductor elements on the base material with an insulating material,
wherein the first wiring has finer wiring than the second wiring.

5. The method for manufacturing a semiconductor device according to claim 1,
wherein the wiring board includes a base insulating layer and the first wiring provided on the base insulating layer, and the first wiring includes wiring having a line width of 5 μm or less.

6. The method for manufacturing a semiconductor device according to claim 5,
wherein the base insulating layer contains a glass cloth.

7. The method for manufacturing a semiconductor device according to claim 6,
wherein a base material of the glass cloth has a thickness of 30 μm or more and 500 μm or less.

8. The method for manufacturing a semiconductor device according to claim 5,
wherein the base insulating layer has a thickness of 50 μm or more and 300 μm or less.

9. The method for manufacturing a semiconductor device according to claim 5,
wherein a thickness variation of the base insulating layer is 1% or less of an average thickness of the base insulating layer.

10. The method for manufacturing a semiconductor device according to claim 5,
wherein the wiring board includes a wiring insulating layer covering the first wiring on the base insulating layer, and
wherein an insulating material forming at least one of the base insulating layer and the wiring insulating layer has a thermal expansion coefficient of 80 ppm/° C. or less.

11. The method for manufacturing a semiconductor device according to claim 10,
wherein the base insulating layer is thicker than the wiring insulating layer.

12. The method for manufacturing a semiconductor device according to claim 5,
wherein a surface of the base insulating layer on which the first wiring is formed has a surface roughness of 200 nm or less.

13. The method for manufacturing a semiconductor device according to claim 5,
wherein the base insulating layer is a laminate including a first insulating layer and a second insulating layer, and
wherein a surface roughness of the first insulating layer in contact with the first wiring is larger than a surface roughness of the second insulating layer.

14. The method for manufacturing a semiconductor device according to claim 13,
wherein the first insulating layer contains a glass cloth, and the second insulating layer does not contain a glass cloth.

15. The method for manufacturing a semiconductor device according to claim 1,
wherein the first wiring is directly connected to at least some of the connection terminals of the plurality of semiconductor elements.

16. The method for manufacturing a semiconductor device according to claim 1,
wherein the first wiring of the wiring board is connected to at least two of the plurality of semiconductor elements.

17. The method for manufacturing a semiconductor device according to claim 1,
wherein the second wiring includes a first end and a second end on a side opposite to the first end, and
wherein the second wiring is connected to at least some of the connection terminals of the plurality of semiconductor elements at the first end and is exposed from an insulating material covering the second wiring and connected to an external terminal at the second end.

18. The method for manufacturing a semiconductor device according to claim 17,
wherein the insulating material covering the second wiring does not contain a glass cloth.

19. A wiring board used in the method for manufacturing a semiconductor device according to claim 1, comprising:
a base insulating layer; and
a first wiring provided on the base insulating layer and including wiring having a line width of 5 μm or less,
wherein the wiring board has a surface area of 2500 mm² or less.

20. A semiconductor device, comprising:
a device wiring layer;
a plurality of semiconductor elements arranged on the device wiring layer; and
an insulation encapsulating portion that covers the plurality of semiconductor elements with an insulating material,
wherein a wiring board having fine wiring connected to the plurality of semiconductor elements so as to bridge over the plurality of semiconductor elements is embedded in the device wiring layer.
